(19) United States
(12) Patent Application Publication
(10) Pub. No.: US 2012/0099285 A1
(43) Pub. Date: Apr. 26, 2012

(54) LAMINATED SUBSTRATE WITH COILS

(76) Inventors: Jeff BIAR, Taipei County (TW); Chih-Kung HUANG, Taipei County (TW)

(21) Appl. No.: 13/014,214

(22) Filed: Jan. 26, 2011

(30) Foreign Application Priority Data
Oct. 22, 2010 (TW) 99220525

(51) Int. Cl. H05K 1/16; H01F 5/00

(52) U.S. Cl. 361/765; 336/200

(57) ABSTRACT

A substrate for chip packaging includes a laminated board made of a plurality of ferrite sheets and a coil component disposed on the board. The coil component includes a first coil conductor, a second coil conductor, and a first via-hole conductor. The first coil conductor is disposed on a surface of a first sheet of the board. The second coil conductor is disposed on a surface of a second sheet of the board. The first via-hole conductor includes a first through hole formed at the first sheet and a first conductor filled in the first through hole. The substrate further includes a top surface having a plurality of first conductive pads, and a bottom surface having a plurality of second conductive pads. Each of the first conductive pads is electrically connected with each of the second conductive pads.

### BACKGROUND OF THE INVENTION

1. Field of the Invention

The present invention relates to a substrate for chip packaging, and more particularly, to a laminated substrate with coils that can be applied in chip packaging.

2. Description of the Related Art

The conventional substrates for chip packaging are generally made of nonmagnetic-permeability hard materials, such as glass fibers mixed with epoxy resin. Thus, to be applied in a power IC chip package, such prior art substrates need a discrete inductor disposed thereon. The result is that the whole volume of the power IC chip package is too bulky to meet the nowadays demands for miniaturizing and thinning the chip packaging.

### SUMMARY OF THE INVENTION

It is an object of the present invention to provide an improved substrate which is not only suitable for applying in the power IC chip packaging but can sufficiently meet the demands for miniaturizing and thinning the power IC chip packaging.

Accordingly, a substrate for chip packaging according to a preferred embodiment of the present invention includes a laminated board made of a plurality of ferrite sheets and a coil component disposed on the board.

The coil component includes a first coil conductor, a second coil conductor, and a first via-hole conductor to electrically connect the first coil conductor with the second coil conductor. The first coil conductor is disposed on a surface of a first sheet of the board. The second coil conductor is disposed on a surface of a second sheet of the board. The first and second sheets are sequentially laminated. The first via-hole conductor includes a first through hole formed at a predetermined location of the first sheet and a first conductor filled in the first through hole.

The substrate further includes a top surface having a plurality of first conductive pads, and a bottom surface having a plurality of second conductive pads. Each of the first conductive pads is electrically connected with each of the second conductive pads.

### BRIEF DESCRIPTION OF THE DRAWINGS

These and other objects and features of the present invention will become clearer from the following description of the preferred embodiment given with reference to the attached drawings, wherein:

FIG. 1 is a perspective view of a chip package including a substrate according to a preferred embodiment of the present invention;

FIG. 2 is a partly exploded perspective view of the board of the substrate shown in FIG. 1;

FIG. 3 is a cross-sectional view taken along line 3-3 of FIG. 1;

FIG. 4 is a cross-sectional view taken along line 4-4 of FIG. 1;

FIG. 5 is a top side view of the substrate of the chip package shown in FIG. 1; and

FIG. 6 is a bottom side view of the substrate of the chip package shown in FIG. 1.

### DETAILED DESCRIPTION OF PREFERRED EMBODIMENTS

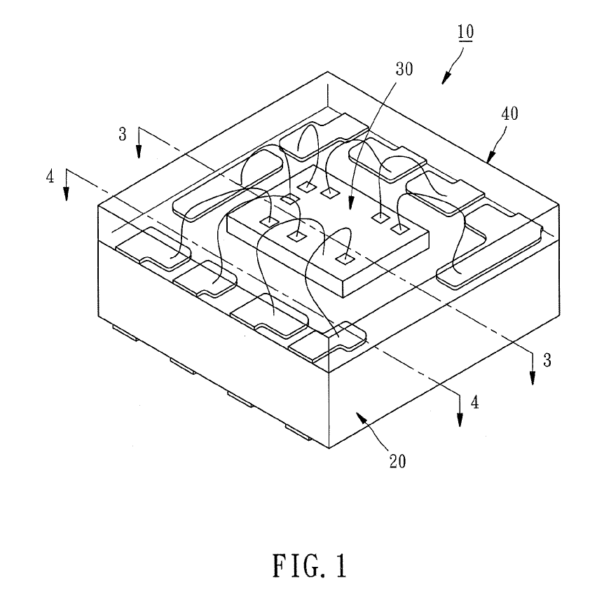

Referring to the drawings, a chip package 10 includes a substrate 20, a power IC chip 30 and a covering 40. It is to be specified that in order to clearly display the structure and relative positions of substrate 20 of the present invention, covering 40 is transparently shown in. FIG. 1.

Substrate 20 includes a board 22 and a coil component 24 disposed in board 22. Board 22 includes a plurality of ferrite sheets 26 and each of sheets 26 is a magnetic-permeability ferrite sheet.

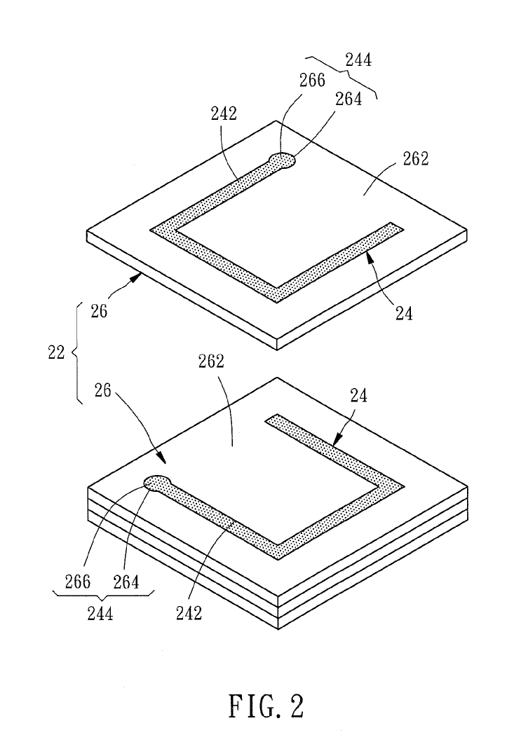

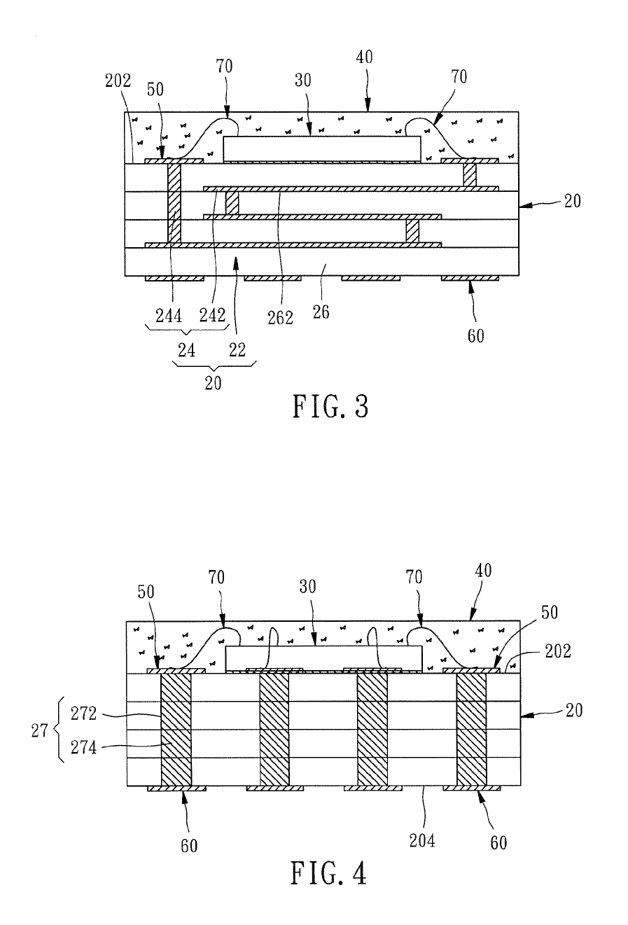

Coil component 24 includes a plurality of coil conductors 242 and a plurality of first via-hole conductors 244. As shown in FIG. 2, each of coil conductors 242 is a conductive paste applied to the upper surface of each of sheets 26 by screen printing or other suitable method. In addition, via-hole conductor 244 has a first through hole 264 and a first conductor 266. First hole 264 is formed at one end of coil conductor 242. First conductor 266 is made of conductive paste and filled in first hole 264

In this embodiment, sheets 26 thus obtained are sequentially laminated and pressure-bonded to form a laminate. The laminate is cut to a predetermined product size, debound, and then fired to obtain sintered board 22. Coil conductors 242 are electrically connected in series through first via-hole conductors 244 to form spiraled coil component 24.

Substrate 20 further includes a top surface 202 and a bottom surface 204. Top surface 202 can be the upper surface of board 22 or the upper surface of an independent sheet laminated on the upper surface of board 22. Similarly, bottom surface 204 can be the bottom surface of board 22 or the bottom surface of an independent sheet laminated on the bottom surface of board 22.

Top surface 202 has a plurality of first conductive pads 50. Bottom surface 204 has a plurality of second conductive pads 60. The disposing way of first and second conductive pads 50, 60 can be a quad flat no leads type or a land grid array type. Each of first conductive pads 50 is electrically connected with each of second conductive pads 60 by a second via-hole conductor 27.

Second through via-hole conductor 27 has a second through hole 272 and a second conductor 274. Second through hole 272 is disposed at board 22 and between each of first conductive pads 50 and each of second conductive pads 60. Second conductor 274 is made of a conductive paste and filled in second through hole 272 (as shown in FIG. 4).

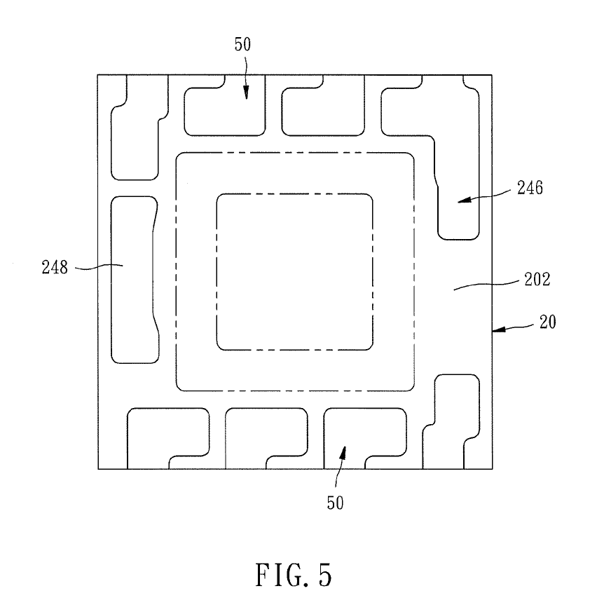

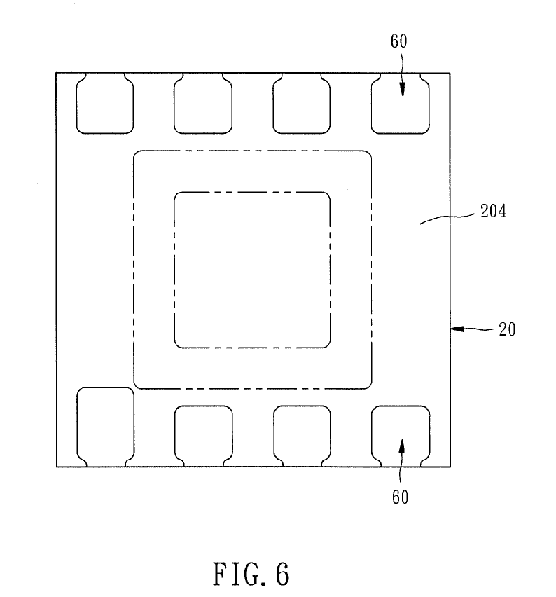

In addition, coil component 24 further has an input end 246 and an output end 248 which are respectively disposed on top surface 202 of substrate 20 (as shown in FIG. 5).

When substrate 20 is used in chip packaging, as shown in FIG. 1, power IC chip 30 is firstly adhered to top surface 202 of substrate 20, and then a plurality of wiring bondings 70 are disposed to electrically connect chip 30 with first conductive pads 50, and lastly a plastic resin is molded over top surface 202 of substrate 20 to form covering 40.

What is claimed is:

1. A substrate for chip packaging, comprising:
a board including a plurality of sequentially laminated and pressure-bonded ferrite sheets;
a coil component disposed in said board, said coil component including a first coil conductor, a second coil conductor, and a first via-hole conductor to electrically connect said first coil conductor with said second coil conductor;
said first coil conductor disposed on a surface of a first sheet of said board, said second coil conductor disposed on a surface of a second sheet of said board, said first via-hole conductor including a first through hole formed at a predetermined location of said first sheet and a first conductor filled in said first through hole; and
said substrate further includes a top surface having a plurality of first conductive pads, and a bottom surface having a plurality of second conductive pads; each of said first conductive pads electrically connected with each of said second conductive pads.

2. The substrate of claim 1, wherein said substrate further including a plurality of second through via-hole conductors, each of said second through via-hole conductors having a second through hole and a second conductor, said second through hole being disposed at said board and between each of first conductive pads and each of second conductive pads, said second conductor being made of a conductive paste and filled in said second through hole.

3. The substrate of claim 1, wherein said coil component further has an input end and an output end which are respectively disposed on said top surface of said substrate.

4. The substrate of claim 1, wherein each of said coil conductors is a conductive paste applied to the upper surface of each of said sheets by screen printing.

5. The substrate of claim 4, wherein said first conductor of said first via-hole conductor is a conductive paste filled in said first through hole.

6. A chip package comprising:
a substrate including:
a board including a plurality of sequentially laminated and pressure-bonded ferrite sheets;
a coil component disposed in said board, said coil component including a first coil conductor, a second coil conductor, and a first via-hole conductor to electrically connect said first coil conductor with said second coil conductor;
said first coil conductor disposed on a surface of a first sheet of said board, said second coil conductor disposed on a surface of a second sheet of said board, said first via-hole conductor including a first through hole formed at a predetermined location of said first sheet and a first conductor filled in said first through hole;
a top surface having a plurality of first conductive pads;
a bottom surface having a plurality of second conductive pads; each of said first conductive pads electrically connected with each of said second conductive pads;
a chip disposed on said top surface of said substrate;
a plurality of wiring bondings to electrically connect said chip with said first conductive pads; and
a covering applied on said top surface of said substrate.

7. The package of claim 6, wherein said substrate further including a plurality of second through via-hole conductors, each of said second through via-hole conductors having a second through hole and a second conductor, said second through hole being disposed at said board and between each of first conductive pads and each of second conductive pads, said second conductor being made of a conductive paste and filled in said second through hole.

8. The package of claim 6, wherein said coil component further has an input end and an output end which are respectively disposed on said top surface of said substrate.
